(19) United States
(12) Patent Application Publication
(10) Pub. No.: US 2026/0082957 A1
(43) Pub. Date: Mar. 19, 2026

(54) ELECTRONIC DEVICE AND MANUFACTURING METHOD THEREOF

(71) Applicant: InnoLux Corporation, Miao-Li County (TW)

(72) Inventor: Po-Yun HSU, Miao-Li County (TW)

(73) Assignee: InnoLux Corporation, Miao-Li County (TW)

(21) Appl. No.: 19/304,625

(22) Filed: Aug. 20, 2025

Related U.S. Application Data
(60) Provisional application No. 63/695,851, filed on Sep. 18, 2024.

(30) Foreign Application Priority Data
May 29, 2025 (CN) 202510705408.7

(51) Int. Cl. H01L 23/498; H01L 21/288; H01L 21/66; H01L 25/16

(52) U.S. Cl. CPC H10W 70/65; H10P 14/46; H10P 74/203; H10W 90/00

(57) ABSTRACT

A manufacturing method of an electronic device is provided by the present disclosure. The manufacturing method includes providing a target substrate, and disposing a circuit structure on the target substrate. The process of providing the target substrate includes following steps: (a) providing a base layer; (b) performing a flattening step on the base layer, and then measuring a first thickness variation of the base layer; (c) disposing two planarization layers respectively at two sides of the base layer to form the target substrate; and (d) measuring a second thickness variation of the target substrate, wherein the second thickness variation is less than the first thickness variation.

### CROSS REFERENCE TO RELATED APPLICATION

This application claims the benefit of U.S. Provisional Application No. 63/695,851, filed on Sep. 18, 2024. The content of the application is incorporated herein by reference.

### BACKGROUND OF THE DISCLOSURE

### 1. Field of the Disclosure

The present disclosure relates to an electronic device and manufacturing method thereof, and more particularly to a package element and manufacturing method thereof.

### 2. Description of the Prior Art

As the demand of area for packaging processes increases, a large-sized substrate (such as a glass substrate) is needed to solve the problem of insufficient size of substrate. However, the large-sized substrate formed through current manufacturing methods has the problem of excessively great thickness variation. Therefore, when a circuit structure is disposed on the substrate, the process yield of the circuit structure may be reduced, or a circuit structure having a high fineness of wires may not be formed. Therefore, to solve the above-mentioned problem is still an important issue in the present field.

### SUMMARY OF THE DISCLOSURE

The present disclosure aims at providing an electronic device and a manufacturing method thereof, wherein the substrate used in the manufacturing process of the electronic device may be designed to improve the flatness thereof, thereby improving the process yield of elements or layers on the substrate (or the carrier).

A manufacturing method of an electronic device is provided by the present disclosure. The manufacturing method includes providing a target substrate, and disposing a circuit structure on the target substrate. The process of providing the target substrate includes following steps: (a) providing a base layer; (b) performing a flattening step on the base layer, and then measuring a first thickness variation of the base layer; (c) disposing two planarization layers respectively at two sides of the base layer to form the target substrate; and (d) measuring a second thickness variation of the target substrate, wherein the second thickness variation is less than the first thickness variation.

An electronic device is provided by the present disclosure. The electronic device includes a target substrate and a circuit structure disposed on the target substrate. The target substrate includes a base layer and two planarization layers respectively disposed at two sides of the base layer. The base layer has a first thickness variation, the target substrate has a second thickness variation, and the second thickness variation is less than the first thickness variation.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 shows a flow chart of a manufacturing method of an electronic device according to a first embodiment of the present disclosure.

FIG. 2 to FIG. 5 schematically illustrate a manufacturing process of the electronic device according to the first embodiment of the present disclosure.

FIG. 6 to FIG. 8 schematically illustrate a manufacturing process of an electronic device according to a second embodiment of the present disclosure.

FIG. 9 schematically illustrates a cross-sectional view of an electronic device according to a third embodiment of the present disclosure.

FIG. 10 schematically illustrates a cross-sectional view of an electronic device according to a fourth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that in the present disclosure, when an element is referred to as being “disposed on” another element, the order of the process steps of the element and the another element are not limited. Or, in the present disclosure, when an element is referred to as being “disposed on” another element, it includes the case that the element is formed on a sidewall of the another element. When an element or layer is referred to as being “disposed on” or “connected to” another element or layer, it can be directly on or directly connected to the other element or layer, or intervening elements or layers may be presented (indirectly). In the present disclosure, when an element is referred to as being “disposed on” another element, the order of the process steps of the element and the another element are not limited. In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

According to the present disclosure, the depth, the thickness, the length, the width and the pore size may be measured through optical microscope (OM), electronic microscope (such as scanning electron microscope (SEM)) or other suitable ways, but not limited thereto.

In the present disclosure, the roughness may be judged by observing through SEM. On an uneven surface, it can be seen that the peaks and valleys of the surface have a distance of 0.15 micrometers (μm) to 1 μm. The measurement of the roughness may be performed by observing the undulations of the surface through SEM, transmission electron microscope (TEM), and the like at the same appropriate magnification, and taking a sample of a unit length (for example, 10 μm) to compare the undulation conditions as its roughness range. Here, “appropriate magnification” means that at least one surface can see the roughness (Rz) or average roughness (Ra) of at least 10 peaks under this magnification.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may be applied to a power module, a semiconductor package device, a display device, a light emitting device, a back-light device, an antenna device, a sensing device or a tiled device, but not limited thereto. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The display device may be a non-self-emissive display device or a self-emissive display device. The sensing device may include a biosensor, a touch sensor, a fingerprint sensor, other suitable sensors or combinations of the above-mentioned sensors. The antenna device may for example include a liquid crystal antenna device or a non-liquid crystal antenna device. The tiled device may for example include a tiled display device or a tiled antenna device, but not limited thereto. The outline of the electronic device may be a rectangle, a circle, a polygon, a shape with curved edge or other suitable shapes. The electronic device may include e electronic elements, wherein the electronic elements may include semiconductor elements. The semiconductor element may be the electronic element including a semiconductor layer or formed through a semiconductor process, but not limited thereto. The electronic elements for example include passive elements or active elements, such as capacitor, resistor, inductor, diode, transistor, integrated circuits, and the like. The diode may include a light emitting diode, a photo diode or a varactor diode. The light emitting diode may for example include an organic light emitting diode (OLED), a mini light emitting diode (mini LED), a micro light emitting diode (micro LED) or a quantum dot light emitting diode (QLED), but not limited thereto. It should be noted that the electronic device may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The manufacturing method of the electronic device of the present disclosure may for example be applied to a wafer-level package (WLP) process or a panel-level package (PLP) process, but not limited thereto. The manufacturing method of the electronic device of the present disclosure may include a chip-first process or a chip-last process, but not limited thereto. The electronic device may include package devices such as high bandwidth memory (HBM) package, system on a chip (SoC), system in a package (SiP), antenna in package (AiP), co-packaged optical (CPO) or combinations of the above-mentioned devices, but not limited thereto.

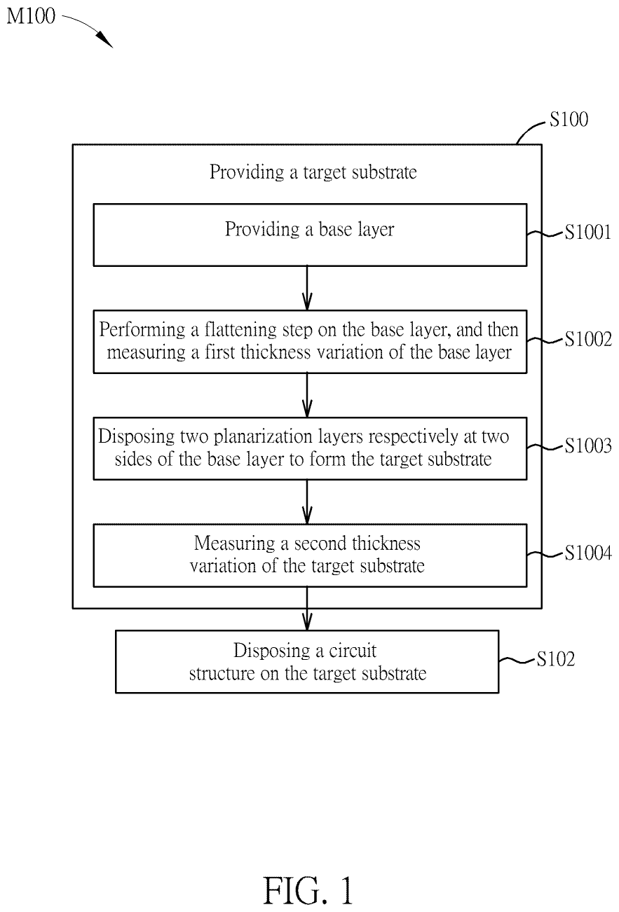

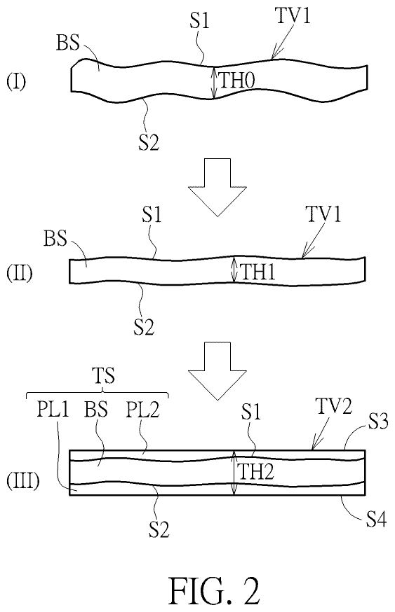

Referring to FIG. 1 to FIG. 5, FIG. 1 shows a flow chart of a manufacturing method of an electronic device according to a first embodiment of the present disclosure, and FIG. 2 to FIG. 5 schematically illustrate a manufacturing process of the electronic device according to the first embodiment of the present disclosure. As shown in FIG. 1, the manufacturing method M100 of the electronic device (that is, the electronic device E0 in the following) of the present embodiment may include following steps:
S100: providing a target substrate; and
S102: disposing a circuit structure on the target substrate.
wherein the process of providing the target substrate (the step S100) includes following steps:
S1001: providing a base layer;
S1002: performing a flattening step on the base layer, and then measuring a first thickness variation of the base layer;
S1003: disposing two planarization layers respectively at two sides of the base layer to form the target substrate; and
S1004: measuring a second thickness variation of the target substrate.

The details of the steps in the manufacturing method M100 will be described in the following.

According to the present embodiment, the manufacturing method M100 of the electronic device may include the step S100: providing a target substrate TS at first. Specifically, the manufacturing process of the target substrate TS may include the step S1001: providing a base layer BS at first, as shown in the structure (I) of FIG. 2. The base layer BS may include any suitable material that can provide a supporting function or a carrying function. For example, the base layer BS may include transparent materials or glass in the present embodiment, but not limited thereto. The transmittance of the base layer BS to white light may for example be greater than or equal to 808. The base layer BS may serve as a large-sized carrier to facilitate the large-area disposition process of elements (such as the circuit structure CS described below) thereon. For example, the base layer BS may be a large-sized glass carrier. In some embodiments, the shape of the base layer BS in the top view direction (that is, a direction parallel to the direction Z) may be a rectangle (for example, a square, but not limited thereto), wherein the length or width of the rectangle may be at least 300 millimeters (mm), but not limited thereto. In such condition, the size of the base layer BS in the top view direction (that is, a direction parallel to the direction Z) may be 300 mm*300 mm. In some embodiments, the size of the base layer BS in the top view direction may be 500 mm*500 mm. In some embodiments, the size of the base layer BS in the top view direction may be 600 mm*600 mm. In some embodiments, the size of the base layer BS in the top view direction may be 700 mm*700 mm or greater than 700 mm*700 mm. In some embodiments, the shape of the base layer BS in the top view direction may be a circle or approximately a circle, wherein the diameter of the circle may be at least 500 mm. In some embodiments, the base layer BS may have other suitable shapes in the top view direction, and is not limited to the above-mentioned shapes. Since the size of the base layer BS is relatively large, the surfaces of the base layer BS (including the surface S1 and the surface S2) may be concave-convex surfaces, or in other words, the base layer BS may have uneven surfaces. In detail, the base layer BS may have a first thickness variation TV1, wherein the first thickness variation TV1 may be greater than 20 micrometers (μm), but not limited thereto. “The first thickness variation TV1” may be a variance of the thickness TH0 of the base layer BS, which may for example be defined by the thicknesses measured at least at five locations of the base layer BS. The thickness TH0 of the base layer BS may for example be the thickness of the base layer BS in the top view direction. It should be noted that since the thickness of the base layer BS may be non-uniform, the thicknesses TH0 measured at different positions may be different. In detail, at least five locations of the base layer BS may be selected at first, and the thicknesses TH0 of the base layer BS at the five locations may be measured. After that, the variance of the measured thicknesses TH0 may be the first thickness variation TV1 of the base layer BS. Specifically, after measuring values of N thicknesses TH0 (these values are represented by THi in formula (1), where i is 1 to N), the average value M of the N thicknesses TH0 may be calculated at first, and then the first thickness variation TV1 may be calculated through the following formula (1), but not limited thereto.

$$TV 1 = \frac{1}{N} {\sum }_{i = 1}^{N} {( T H i - M )}^{2} \qquad ( 1 )$$

After the base layer BS is provided, the manufacturing process of the target substrate TS may further include the step S1002: performing a flattening step on the base layer BS, and then measuring the first thickness variation TV1 of the base layer BS. Specifically, as shown in the structure (II) of FIG. 2, a flattening process may be performed on the surface S1 and/or the surface S2 of the base layer BS to improve the flatness of the surface S1 and the surface S2 or reduce the undulation of the surface S1 and the surface S2. The flattening process of the base layer BS mentioned above may for example include chemical-mechanical polishing (CMP), grinding, sandblasting or other suitable processes. After the flattening step of the base layer BS, the first thickness variation TV1 of the base layer BS may be reduced and may be less than a specific value. In such condition, “the first thickness variation TV1” may be the variance of the thickness TH1 of the base layer BS, and the calculation method thereof may refer to the contents mentioned above. For example, in the present embodiment, the first thickness variation TV1 of the base layer BS measured after the flattening step may be less than or equal to 20 μm (that is, TV1≤20 μm), but not limited thereto. In such condition, when the first thickness variation TV1 of the base layer BS measured after the flattening step is greater than 20 μm, the step S1002 may be performed again, that is, the above-mentioned flattening process may be performed on the surface S1 and/or the surface S2 of the base layer BS again, and then the first thickness variation TV1 is measured. In other words, the flattening step (the step S1002) of the base layer BS mentioned above may be performed repeatedly until the measured first thickness variation TV1 is less than or equal to 20 μm, but not limited thereto. In some embodiments, the step S1002 may be performed repeatedly until the measured first thickness variation TV1 is less than or equal to 18 μm. In some embodiments, the step S1002 may be performed repeatedly until the measured first thickness variation TV1 is less than or equal to 16 μm. It should be noted that the first thickness variation TV1 of the base layer BS may be measured before the flattening step of the base layer BS, and when the measured first thickness variation TV1 is less than or equal to 20 μm, the above-mentioned flattening step of the base layer BS may be skipped, but not limited thereto.

After the flattening step is performed on the base layer BS such that the first thickness variation TV1 of the base layer BS satisfies the above-mentioned condition, the manufacturing process of the target substrate TS further includes the step S1003: disposing two planarization layers respectively at two sides of the base layer BS. Specifically, as shown in the structure (III) of FIG. 2, after the flattening process of the base layer BS is completed, a planarization layer PL2 may be disposed at a side of the surface S1 of the base layer BS, and a planarization layer PL1 may be disposed at a side of the surface S2 of the base layer BS. The planarization layer PL2 may be entirely disposed at a side of the base layer BS and cover the surface S1, and the planarization layer PL1 may be entirely disposed at another side of the base layer BS and cover the surface S2. In other words, the base layer BS may be sandwiched between the planarization layer PL1 and the planarization layer PL2. After the planarization layer PL1 and the planarization layer PL2 are disposed, the target substrate TS may be formed. The planarization layer PL1 and the planarization layer PL2 may include any material that can provide a flat surface. In addition, the transmittances of the planarization layer PL1 and the planarization layer PL2 to the light with a wavelength from 300 nanometers (nm) to 700 nm may be greater than or equal to 70%, but not limited thereto. According to some embodiments, the transmittance of the planarization layer PL1 may be greater than the transmittance of the planarization layer PL2 to improve the quality of release, but not limited thereto. That is, the materials satisfying the above-mentioned characteristics may serve as the materials of the planarization layer PL1 and the planarization layer PL2. It should be noted that the planarization layer PL1 and the planarization layer PL2 may include the same material or include different materials, it is not limited in the present disclosure. In some embodiments, the planarization layer may be disposed only at a side of the base layer BS. The planarization layer PL1 and the planarization layer PL2 may include organic materials or inorganic materials, or the materials of the planarization layer PL1 and the planarization layer PL2 may include silicon-containing compounds, but not limited thereto. The planarization layer PL1 and the planarization layer PL2 may include materials having affinity with the base layer BS. In detail, van der waals force may be included between the planarization layer PL1 (or the planarization layer PL2) and the base layer BS. The planarization layer PL1 and the planarization layer PL2 may have good leveling properties, such that the planarization layer PL1 and the planarization layer PL2 may fill the concaves of the base layer BS after the planarization layer PL1 and the planarization layer PL2 are provided on the base layer BS to make the target substrate TS has a lower thickness variation and make the two opposite sides of the target substrate TS have lower surface roughness.

After the target substrate TS is formed, the step S1004 may be performed to measure the second thickness variation TV2 of the target substrate TS. The definition of the second thickness variation TV2 may refer to the definition of the first thickness variation TV1 mentioned above. Specifically, at least five locations of the target substrate TS may be selected at first, and the thicknesses TH2 of the target substrate TS at the five locations may be measured. After that, the variance of the measured thicknesses TH2 may be the second thickness variation TV2 of the target substrate TS. The thickness TH2 may be the thickness of the target substrate TS in the top view direction. After the planarization layer PL1 and the planarization layer PL2 are disposed, the surface S3 of the planarization layer PL2 away from the base layer BS and the surface S4 of the planarization layer PL1 away from the base layer BS may have a greater flatness than the surfaces S1 and the surface S2 of the base layer BS. The surface S3 and the surface S4 mentioned above may also be regarded as the surfaces of the target substrate TS. In other words, the surfaces of the target substrate TS may be flatter than the surfaces of the base layer BS. Therefore, the second thickness variation TV2 of the target substrate TS may be less than the first thickness variation TV1 of the base layer BS. According to the present embodiment, after the planarization layers are respectively disposed at two sides of the base layer BS to form the target substrate TS, the second thickness variation TV2 of the target substrate TS may be less than a specific value. For example, in the present embodiment, the second thickness variation TV2 of the target substrate TS formed by disposing the planarization layers may be less than or equal to 3 μm (that is, TV2≤3 μm), but not limited thereto. In some embodiments, after the target substrate TS is formed, when the measured second thickness variation TV2 of the target substrate TS is greater than 3 μm (for example, excessive surface undulation of the planarization layer due to dust or other factors), the planarization layer PL1 and the planarization layer PL2 may be removed at first, and then the step of disposing the planarization layers (that is, the step S1003) and the step of measuring the second thickness variation TV2 (that is, the step S1004) mentioned above may be performed again. It should be noted that the above-mentioned processes (that is, the step S1003 and the step S1004) may be performed repeatedly until the measured second thickness variation TV2 is less than or equal to 3 μm. In some embodiments, after the target substrate TS is formed, when the measured second thickness variation TV2 of the target substrate TS is greater than 3 μm, a flattening step may further be performed on the planarization layer PL1 and the planarization layer PL2 to improve the flatness of the planarization layer PL1 and the planarization layer PL2, thereby reducing the measured second thickness variation TV2. The flattening step described herein may refer to the contents related to the flattening step of the base layer BS mentioned above, and will not be redundantly described. It should be noted that the flattening step of the planarization layer PL1 and the planarization layer PL2 may be performed repeatedly until the measured second thickness variation TV2 is less than or equal to 3 μm.

Through the above-mentioned steps, the target substrate TS may be formed, wherein the target substrate TS may be a composite layer which includes the base layer BS and two planarization layers (that is, the planarization layer PL1 and the planarization layer PL2) respectively disposed at two sides of the base layer BS. The planarization layer PL1 and the planarization layer PL2 may contact the base layer BS, but not limited thereto. Through the disposition of the planarization layer PL1 and the planarization layer PL2, the second thickness variation TV2 of the target substrate TS may be less than the first thickness variation TV1 of the base layer BS disposed in the target substrate TS. As mentioned above, in the present embodiment, the first thickness variation TV1 of the base layer BS in the target substrate TS may be less than or equal to 20 μm, and the second thickness variation TV2 of the target substrate TS may be less than or equal to 3 μm, but not limited thereto. The target substrate TS may serve as a carrier used for disposing other elements or layers thereon.

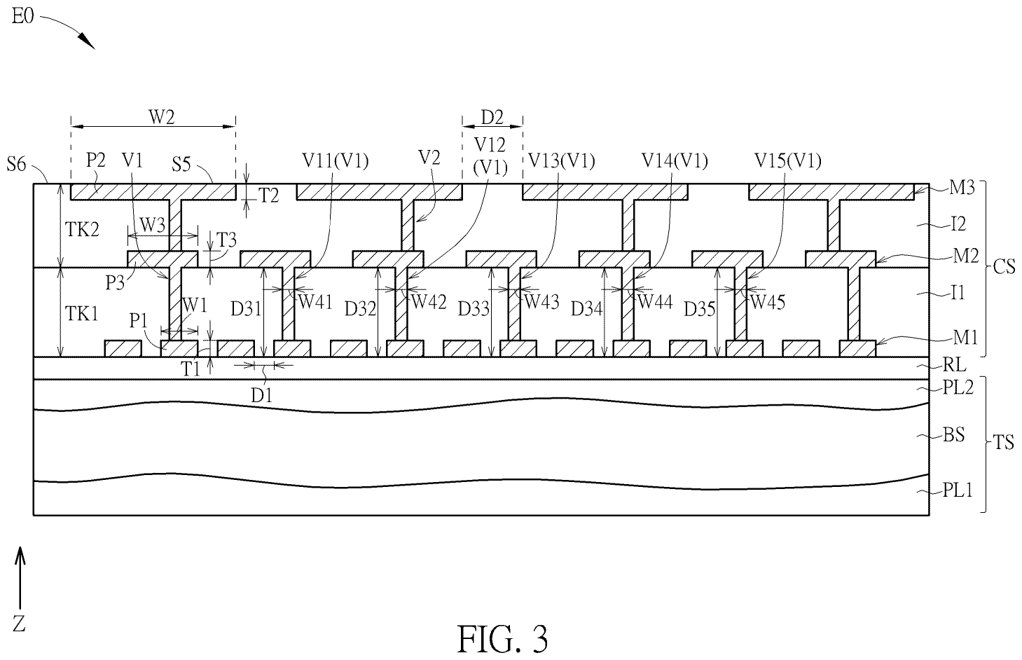

After the target substrate TS is formed, the manufacturing method M100 of the electronic device may further include the step S102: disposing a circuit structure CS on the target substrate TS. Specifically, as shown in FIG. 3, after the target substrate TS is formed, a release layer RL may be disposed on the target substrate TS, and then the circuit structure CS may be disposed on the release layer RL. It should be noted that “the circuit structure CS is disposed on the target substrate TS” described herein may include the embodiment that the circuit structure CS is formed on the target substrate TS and the embodiment that the circuit structure CS is formed at first, and then the circuit structure CS is transferred to the target substrate TS. The circuit structure CS may be disposed at any side of the target substrate TS where the planarization layer is located. For example, as shown in FIG. 3, the circuit structure CS may be disposed at the side of the target substrate TS where the planarization layer PL2 is located, that is, the planarization layer PL2 may be located between the circuit structure CS and the base layer BS, but not limited thereto. In some embodiments, the circuit structure CS may be disposed at the side of the target substrate TS where the planarization layer PL1 is located, that is, the planarization layer PL1 may be located between the circuit structure CS and the base layer BS.

The circuit structure CS may include various kinds of wires, circuits or electronic units. The electronic unit may include any suitable active element and/or passive element. The circuit structure CS may include any suitable structure formed by stacking conductive layer(s) and insulating layer(s), wherein the conductive layer(s) may be used for forming the wires, the circuits or the electronic units mentioned above, but not limited thereto. According to some embodiments, after the release layer RL is disposed, conductive layer(s) and insulating layer(s) may be alternately formed on the release layer RL to form the circuit structure CS. For example, as shown in FIG. 3, the circuit structure CS may include a first conductive layer M1, a second conductive layer M2, a third conductive layer M3, an insulating layer I1 and an insulating layer 12, but not limited thereto. The insulating layer I1 is located between the first conductive layer M1 and the second conductive layer M2, and the insulating layer 12 is located between the second conductive layer M2 and the third conductive layer M3. The first conductive layer M1 may be directly disposed on the release layer RL, but not limited thereto. In some embodiments, a buffer layer (not shown) or other suitable layers may be disposed between the first conductive layer M1 and the release layer RL. The second conductive layer M2 is disposed on the first conductive layer M1 and may be electrically connected to the first conductive layer M1 through a via (for example, the via V1) penetrating the insulating layer I1. The third conductive layer M3 is disposed on the second conductive layer M2 and may be electrically connected to the second conductive layer M2 through a via (for example, the via V2) penetrating the insulating layer 12. In some embodiments, as shown in FIG. 3, the uppermost conductive layer (or the conductive layer farthest from the target substrate TS) in the circuit structure CS (for example, the third conductive layer M3) may be an under bump metallization (UBM) layer disposed at the surface of the insulating layer 12, wherein the surface S5 of the third conductive layer M3 may be aligned with the surface S6 of the insulating layer 12. In some embodiments, a portion of the surface S5 of the third conductive layer M3 may be a recessed surface (not shown). In some embodiments, the third conductive layer M3 may be disposed on the insulating layer 12, that is, the third conductive layer M3 may protrude from the surface of the insulating layer 12. The first conductive layer M1, the second conductive layer M2 and the third conductive layer M3 may include any suitable conductive material, such as metal materials, but not limited thereto. The insulating layer I1 and the insulating layer 12 may include any suitable organic insulating material or inorganic insulating material. For example, the insulating layer I1 and the insulating layer 12 may include polyimide (PI), photosensitive polyimide (PSPI), epoxy resin, polymers, ABF material, silicon oxides (SiOₓ), silicon nitride (SiNₓ), other suitable materials or combinations of the above-mentioned materials. It should be noted that the circuit structure CS shown in FIG. 3 is exemplary, and the structure of the circuit structure CS of the present embodiment (for example, the number of conductive layers and insulating layers or the layout of the conductive layers) is not limited to what is shown in FIG. 3. In some embodiments, the circuit structure CS may include a redistribution structure. The redistribution structure may be the structure capable of adjusting the positions of the signal input terminal and the signal output terminal or adjusting the layout of wires. In other words, the circuits may be extended to have a greater spacing, or a circuit may be redistributed to another circuit with different spacing through the redistribution structure. Therefore, the circuit may be redistributed, and/or the fan out area of the circuit may increase.

According to the present embodiment, when forming the circuit structure CS on the target substrate TS, the wire with a lower size may be formed at first, or the conductive layer used for forming the wire with a lower size may be formed at first. In such condition, the size of the wire formed by the conductive layer closer to the target substrate TS may be less than the size of the wire formed by the conductive layer farther from the target substrate TS. Specifically, in the present embodiment, the sizes of the wires formed by the conductive layers of the circuit structure CS may gradually increase as being away from the target substrate TS, but not limited thereto. For example, as shown in FIG. 3, the conductive layers of the circuit structure CS may include a conductive layer (that is, the first conductive layer M1) closest to the target substrate TS and another conductive layer (that is, the third conductive layer M3) farthest from the target substrate TS, wherein the first conductive layer M1 may be patterned to include a plurality of conductive portions P1 separated from each other, and the third conductive layer M3 may be patterned to include a plurality of conductive portions P2 separated from each other. Each of the conductive portions P1 may serve as a wire or a wire pattern formed by the first conductive layer M1, and each of the conductive portions P2 may serve as a wire or a wire pattern formed by the third conductive layer M3, but not limited thereto. According to the present embodiment, the size of one of the conductive portions P1 may be less than the size of one of the conductive portions P2. “The size of the conductive portion” described herein may for example be the width or thickness of the conductive portion in a cross-sectional view of the circuit structure CS, an area of the conductive portion in a top view of the circuit structure CS, or a pitch between two adjacent conductive portions, but not limited thereto. In detail, one of the conductive portions P1 may have a width W1, and one of the conductive portions P2 may have a width W2, wherein the width W1 may be less than the width W2. In addition, a conductive layer (for example, the second conductive layer M2) located between the first conductive layer M1 and the third conductive layer M3 may be patterned to include a plurality of conductive portions P3 separated from each other, and one of the conductive portions P3 may have a width W3, wherein the width W3 may be between the width W1 and the width W2, or in other words, the width W3 may be greater than the width W1 and less than the width W2 (that is, W1<W3<W2). In some embodiments, one of the conductive portions P1 may have a thickness T1, and one of the conductive portions P2 may have a thickness T2, wherein the thickness T1 may be less than the thickness T2. In addition, one of the conductive portions P3 may have a thickness T3, wherein the thickness T3 may be greater than the thickness T1 and less than the thickness T2 (that is, T1<T3<T2). The width W1 and the thickness T1 mentioned above may also be regarded as the width and the thickness of the wire formed by the first conductive layer M1 respectively; and the width W2 and the thickness T2 mentioned above may also be regarded as the width and the thickness of the wire formed by the third conductive layer M3 respectively. In other words, the width and/or the thickness of the wire closer to the target substrate TS may be respectively less than the width and/or the thickness of the wire farther from the target substrate TS. In some embodiments, in a top view of the circuit structure CS, an area of one of the conductive portions P1 may be less than an area of one of the conductive portions P2. In addition, in the present embodiment, the circuit structure CS may include an insulating layer (that is, the insulating layer I1) closest to the target substrate TS and an insulating layer (that is, the insulating layer 12) farthest from the target substrate TS, wherein the insulating layer I1 has a thickness TK1, the insulating layer 12 has a thickness TK2, and the thickness TK1 may be less than the thickness TK2.

In addition, in the present embodiment, the number of the wires formed by the first conductive layer M1 closest to the target substrate TS may be greater than the number of the wires formed by the third conductive layer M3 farthest from the target substrate TS. In other words, the number of the conductive portions P1 may be greater than the number of the conductive portions P2. In addition, the number of the plurality of conductive portions P3 included in the second conductive layer M2 may be less than the number of the conductive portions P1 and greater than the number of the conductive portions P2. Specifically, in the circuit structure CS, the number of conductive portions included in the conductive layer may gradually decrease as the distance between the conductive layer and the target substrate TS increases, but not limited thereto. In some embodiments, each of the conductive portions P1 and the conductive portions P2 located at both sides of the circuit structure CS may serve as an input/output point (I/O point) connected to other electronic elements. That is, the number of the I/O points located at a side of the circuit structure CS closer to the target substrate TS may be greater than the number of the I/O points located at another side of the circuit structure CS farther from the target substrate TS. In other words, when forming the circuit structure CS on the target substrate TS, the conductive layer having a greater number of I/O points (or conductive portions) may be formed at first. In such condition, in a cross-sectional view of the circuit structure CS, a distance D1 may be included between two adjacent conductive portions P1 (or two adjacent I/O points) in the first conductive layer M1, and a distance D2 may be included between two adjacent conductive portions P2 (or two adjacent I/O points) in the third conductive layer M3, wherein the distance D1 may be less than the distance D2. In some embodiments, the conductive portions P1 and the conductive portions P2 (or the I/O points) may be arranged at a specific pitch, and in such condition, the above-mentioned distance D1 may be regarded as the pitch of the I/O points in the first conductive layer M1, and the above-mentioned distance D2 may be regarded as the pitch of the I/O points in the third conductive layer M3. After the circuit structure CS is disposed through the above-mentioned way, the electronic device E0 shown in FIG. 3 may be formed, wherein the electronic device E0 may include the target substrate TS and the circuit structure CS disposed on the target substrate TS.

According to the present embodiment, after the target substrate TS is provided as a carrier through the above-mentioned way, when forming the circuit structure CS on the carrier, the possibility of excessive variation in size of the wires of the circuit structure CS due to excessively large area of the carrier may be reduced while increasing the process area, thereby improving the process of the circuit structure CS. Or, by taking the target substrate TS as the carrier, the circuit structure CS having wires with greater fineness may be formed. In addition, by forming the conductive layer including a greater number of conductive portions (or I/O points) or wires having a lower size, the possibility that the manufacturing process of high-density I/O points or wires (for example, formed by the first conductive layer M1) in the circuit structure CS is affected by the uneven surface of the carrier may be reduced. Therefore, the flatness of high-density I/O points or wires in the circuit structure CS may be improved. In detail, by taking the target substrate TS as the carrier, the formed circuit structure CS may have following characteristics. As shown in FIG. 3, the circuit structure CS (or the insulating layer I1 of the circuit structure CS) may include a plurality of vias corresponding to (or contacting) the first conductive layer M1 closest to the target substrate TS, wherein the variation of the widths of the vias may be between 0.1 μm and 2 μm (that is, 0.1 μm<variation<2 μm). That is, by taking the target substrate TS as the carrier to form the circuit structure CS, the width difference between the vias in the insulating layer (such as the insulating layer I1 closest to the target substrate TS) may be reduced. The definition of the variation of the widths of the vias may refer to the definition of the first thickness variation mentioned above. For example, at least 5 vias in the insulating layer I1 may be confirmed at first, such as the via V11, the via V12, the via V13, the via V14 and the via V15 having a width W41, a width W42, a width W43, a width W44 and a width W45 respectively, wherein the variation of the width W41, the width W42, the width W43, the width W44 and the width W45 may be between 0.1 μm and 2 μm, but not limited thereto. “The width of the via” mentioned above may for example be the maximum width of the via in a cross-sectional view of the circuit structure CS. In addition, a plurality of distances may respectively be included between the plurality of conductive portions P1 of the first conductive layer M1 closest to the target substrate TS and the conductive portions P3 of the second conductive layer M2 to which the conductive portions P1 are electrically connected, wherein the variation of the distances may be between 0.01 μm and 1 μm (that is, 0.01 μm<variation<1 μm). That is, by taking the target substrate TS as the carrier to form the circuit structure CS, the difference between the above-mentioned distances may be reduced. For example, at least 5 conductive portions P1 may be confirmed at first, and the conductive portions P3 electrically connected to these conductive portions P1 may further be confirmed, thereby defining the distances between these conductive portions P1 and conductive portions P3, such as the distance D31, the distance D32, the distance D33, the distance D34 and the distance D35, wherein the variation of the distance D31, the distance D32, the distance D33, the distance D34 and the distance D35 may be between 0.01 μm and 1 μm. The distance D31 to the distance D35 mentioned above may for example be defined as the distances between the bottom surface of the first conductive layer M1 and the bottom surface of the second conductive layer M2 in the top view direction (that is, the direction Z). In other words, the distance D31 to the distance D35 mentioned above may also be regarded as the thicknesses of the insulating layer (that is, the insulating layer I1) closest to the target substrate TS, that is, the variation of the thickness TK1 of the insulating layer I1 may be between 0.01 μm and 1 μm.

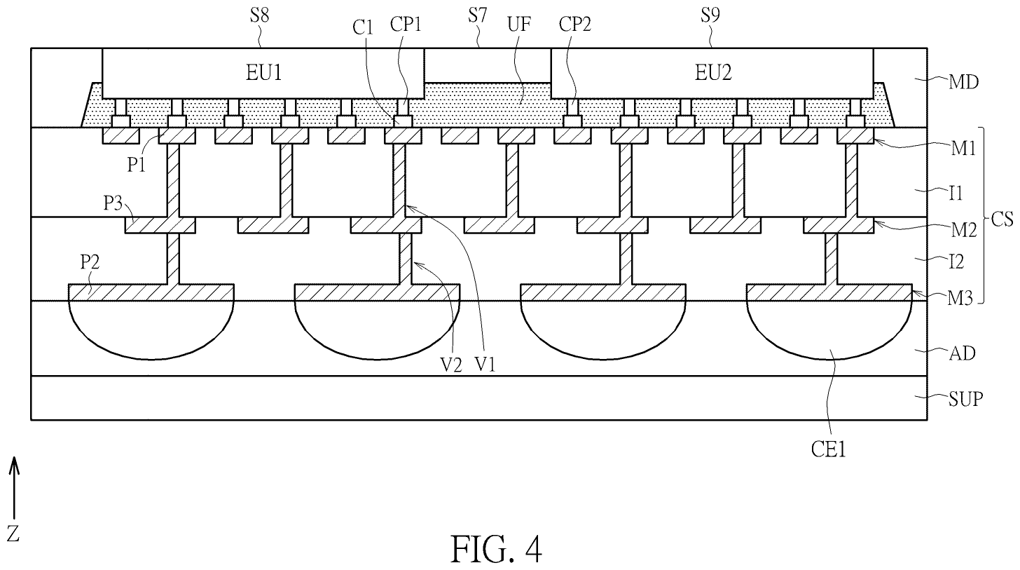

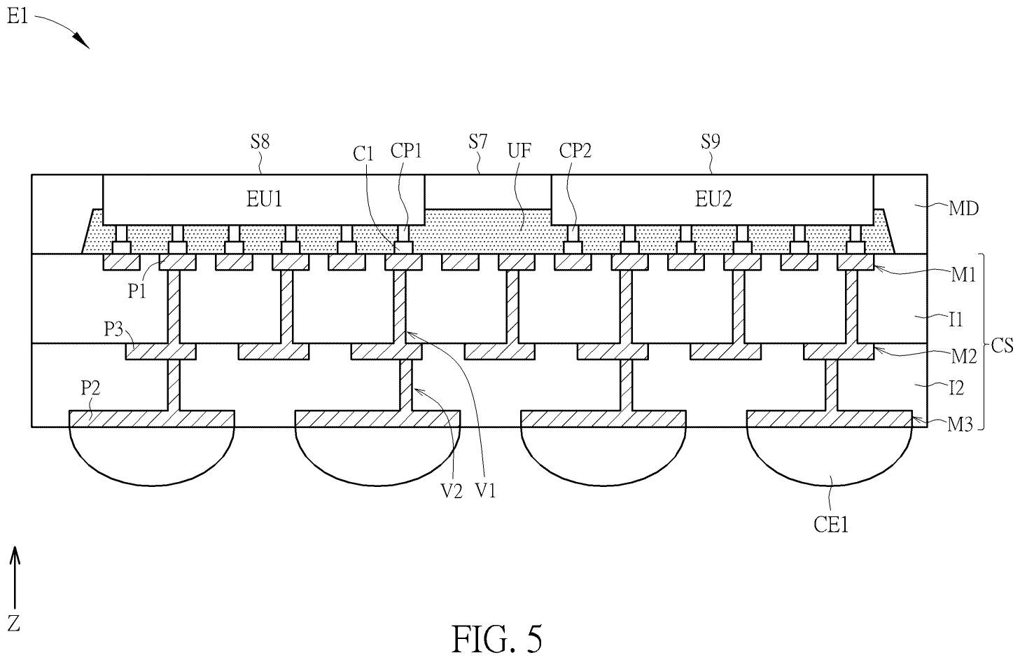

According to the present embodiment, after the electronic device E0 shown in FIG. 3 is formed, other electronic devices may further be formed through the electronic device E0, such as the electronic device E1 shown in FIG. 5. Specifically, as shown in FIG. 4, after the electronic device E0 is formed, the manufacturing method of the electronic device E1 further includes disposing at least one connecting element CE1 at a side of the circuit structure CS adjacent to the third conductive layer M3. The connecting element CE1 may be disposed corresponding to the third conductive layer M3 (or the conductive portions P2 of the third conductive layer M3) and may contact the third conductive layer M3 (or the conductive portions P2 of the third conductive layer M3), such that the connecting element CE1 may be electrically connected to the circuit structure CS. Although it is not shown in the figure, after the connecting element CE1 is disposed, the circuit structure CS may be located between the target substrate TS and the connecting element CE1. The connecting element CE1 may for example include solder, but not limited thereto. The target substrate TS may be used to provide supporting function during the disposition of the connecting element CE1. After the connecting element CE1 is disposed, an adhesive layer AD may be disposed on the connecting element CE1, and a supporting layer SUP may be disposed on the adhesive layer AD. Specifically, after the adhesive layer AD is disposed on the connecting element CE1, the supporting layer SUP may be attached to the circuit structure CS through the adhesive layer AD. In some embodiments, the adhesive layer AD may cover the connecting element CE1 and contact the circuit structure CS (for example, in contact with the insulating layer 12), as shown in FIG. 4, but not limited thereto. In such condition, the adhesive layer AD may be used to reduce the possibility that the connecting element CE1 is affected by the external environment (such as moisture and oxygen). In some embodiments, the adhesive layer AD may be disposed on the connecting element CE1 but not in contact with the circuit structure CS.

After the connecting element CE1 is disposed, the manufacturing method of the electronic device E1 may further include removing the target substrate TS, and disposing at least one electronic element at a side of the circuit structure CS adjacent to the first conductive layer M1. Specifically, after the connecting element CE1 is formed, the target substrate TS may be separated from the circuit structure CS by removing the release layer RL. After that, the structure may be flipped, such that the supporting layer SUP is located below the circuit structure CS, and conductive elements C1 may be disposed on the first conductive layer M1 (or the conductive portions P1 of the first conductive layer M1). The conductive elements C1 may correspond to the first conductive layer M1 (or the conductive portions P1 of the first conductive layer M1) and contact the first conductive layer M1 (or the conductive portions P1 of the first conductive layer M1), such that the conductive elements C1 may be electrically connected to the circuit structure CS. After that, an electronic element EU1 and an electronic element EU2 may be disposed at a side of the circuit structure CS adjacent to the first conductive layer M1. Specifically, the conductive pads CP1 of the electronic element EU1 and the conductive pads CP2 of the electronic element EU2 may contact the conductive elements C1, thereby being bonded to the circuit structure CS through the conductive elements C1. The supporting layer SUP may provide supporting function during the disposition of the electronic element EU1 and the electronic element EU2. In some embodiments, the conductive pads CP1 of the electronic element EU1 and the conductive pads CP2 of the electronic element EU2 may directly contact the conductive layer (that is, the first conductive layer M1) of the circuit structure CS. For example, the electronic element EU1 and the electronic element EU2 may be electrically connected to the circuit structure CS through hybrid bonding, but not limited thereto. In such condition, the above-mentioned conductive element C1 is not needed. The electronic element EU1 and the electronic element EU2 may respectively include a semiconductor unit, a memory unit, an antenna unit, a sensing unit, a capacitor or other suitable active or passive electronic elements. In some embodiments, the electronic element EU and the electronic element EU2 disposed at a side of the circuit structure CS adjacent to the first conductive layer M1 may respectively include an electronic element with great number of I/O points or high density of I/O points. For example, although it is not shown in the figure, the circuit structure CS may further be electrically connected to another electronic element through the connecting element CE1, wherein the number and/or density of the I/O points in the another electronic element being electrically connected to the circuit structure CS may be less than the number and/or density of the I/O points in the electronic element EU1 and the electronic element EU2 being electrically connected to the circuit structure CS, but not limited thereto.

After the electronic element EU1 and the electronic element EU2 are disposed, the manufacturing method of the electronic device E1 further includes the step of disposing an underfill layer UF and a molding layer MD. Specifically, after the electronic element EU1 and the electronic element EU2 are bonded to the circuit structure CS, the underfill layer UF may be disposed at a side of the circuit structure CS adjacent to the first conductive layer M1. The underfill layer UF may be disposed between the circuit structure CS and the electronic element EU1 (and the electronic element EU2) and may surround the conductive elements C1, the conductive pads CP1 and/or the conductive pads CP2. In some embodiments, the underfill layer UF may further surround the electronic element EU1 and the electronic element EU2. In the present disclosure, “an element surrounds another element” may represent that the element may contact at least a portion of the side surface of the another element. In other words, the underfill layer UF may further contact at least a portion of the side surfaces of the electronic element EU1 and the electronic element EU2, as shown in FIG. 4, but not limited thereto. The underfill layer UF may include any suitable insulating material, such as epoxy resin or acrylic resin, but not limited thereto. The underfill layer UF may provide moisture-and-oxygen blocking effect to the conductive elements C1, the conductive pads CP1 and/or the conductive pads CP2. After the underfill layer UF is disposed, the molding layer MD may be disposed at a side of the circuit structure CS adjacent to the first conductive layer M1, wherein the molding layer MD may surround the electronic element EU1, the electronic element EU2 and the underfill layer UF, thereby encapsulating the electronic element EU1 and the electronic element EU2. The molding layer MD may include any suitable organic material or inorganic material, such as epoxy molding compound (EMC), epoxy resin, oxides or nitrides, but not limited thereto. In some embodiments, the surface S7 of the molding layer MD opposite to the circuit structure CS may be substantially aligned with the surface S8 of the electronic element EU1 opposite to the circuit structure CS and/or the surface S9 of the electronic element EU2 opposite to the circuit structure CS, that is, the surface S8 of the electronic element EU1 and/or the surface S9 of the electronic element EU2 may be exposed, as shown in FIG. 4. In some embodiments, the molding layer MD may cover the surface S8 of the electronic element EU1 and the surface S9 of the electronic element EU2. After the above-mentioned processes are completed, the structure shown in FIG. 4 may be formed.

After that, as shown in FIG. 5, after the underfill layer UF and the molding layer MD are disposed, the adhesive layer AD and the supporting layer SUP may be removed to form the electronic device E1. That is, the electronic device E1 may be formed by the electronic device E0 shown in FIG. 3 through the above-mentioned manufacturing process. The types of electronic elements included in the electronic element EU1 and the electronic element EU2 may be determined according to the type or purpose of the electronic device E1. According to the present embodiment, since the above-mentioned target substrate TS is used as the carrier to form the circuit structure CS during the manufacturing process of the electronic device E1, the flatness of the elements or layers (including the first conductive layer M1, the conductive elements C1, the conductive pads CP1 and/or the conductive pads CP2) in the circuit structure CS electrically connected to the electronic elements (including the electronic element EU1 and the electronic element EU2) may be improved, thereby improving the reliability of the electronic device E1. As mentioned above, although it is not shown in the figure, the electronic device E1 may further be electrically connected to another electronic element through the connecting element CE1, such that the electronic element EU1 and the electronic element EU2 may be electrically connected to the another electronic element through the circuit structure CS and the connecting element CE1. It should be noted that the structure of the electronic device E1 is not limited to what is shown in FIG. 5 and may include other suitable elements or layers.

Embodiments of forming other electronic devices through the above-mentioned target substrate TS will be described in the following. In order to simplify the description, the same elements or layers in the following embodiments would be labeled with the same symbol, and the features thereof will not be redundantly described. The differences between the embodiments will be detailed in the following.

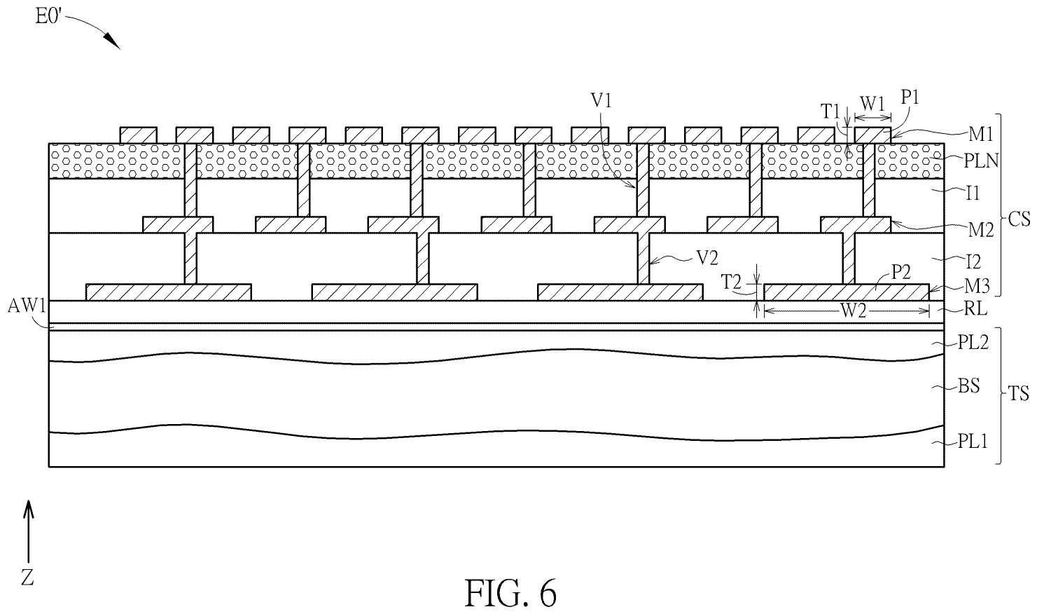

Referring to FIG. 6 to FIG. 8, FIG. 6 to FIG. 8 schematically illustrate a manufacturing process of an electronic device according to a second embodiment of the present disclosure. The manufacturing method of the electronic device E2 of the present embodiment may refer to the manufacturing method M100 mentioned above. Specifically, as shown in FIG. 6, the target substrate TS may be provided at first, and then the circuit structure CS may be disposed on the target substrate TS. The forming method and the detailed structure of the target substrate TS may refer to the contents mentioned above, and will not be redundantly described. After that, the release layer RL may be disposed on the target substrate TS, and the circuit structure CS may be disposed on the release layer RL. In some embodiments, as shown in FIG. 6, an anti-warpage layer AW1 may be optionally disposed on the target substrate TS at first, and then the release layer RL is disposed, that is, the anti-warpage layer AW1 is disposed between the target substrate TS and the release layer RL. Through the disposition of the anti-warpage layer AW1, the influence of stress on subsequent manufacturing processes of the electronic device may be reduced. The anti-warpage layer AW1 may include any suitable organic material or inorganic material. In the present embodiment, when forming the circuit structure CS on the target substrate TS, the wires having a greater size may be formed at first, or the conductive layer used for forming the wires having a greater size may be formed at first. Specifically, the sizes of the wires formed by the conductive layers of the circuit structure CS may gradually decrease as it moves away from the target substrate TS, but not limited thereto. For example, the formation order of the layers of the circuit structure CS of the present embodiment may be opposite to the formation order of the layers of the circuit structure CS shown in FIG. 3, that is, the third conductive layer M3, the insulating layer 12, the second conductive layer M2, the insulating layer I1 and the first conductive layer M1 may be sequentially formed to form the circuit structure CS. In such condition, the size of the wire formed by the conductive layer closer to the target substrate TS may be greater than the size of the wire formed by the conductive layer farther from the target substrate TS. For example, as shown in FIG. 6, the plurality of conductive layers of the circuit structure CS may include the third conductive layer M3 closest to the target substrate TS and the first conductive layer M1 farthest from the target substrate TS, wherein the size of one of the conductive portions P1 of the first conductive layer M1 may be less than the size of one of the conductive portions P2 of the third conductive layer M3. “The size of the conductive portion” described herein may refer to the contents mentioned above. For example, the width W1 of the conductive portion P1 may be less than the width W2 of the conductive portion P2, or the thickness T1 of the conductive portion P1 may be less than the thickness T2 of the conductive portion P2.

In addition, as shown in FIG. 6, the circuit structure CS of the present embodiment may further include a planarization layer PLN adjacent to the conductive layer used for forming the wires with lower size or adjacent to the conductive layer including a greater number of conductive portions (or I/O points). For example, the planarization layer PLN may be adjacent to the first conductive layer M1 having the smallest conductive portions (that is, the conductive portions P1), but not limited thereto. In other words, the planarization layer PLN may be adjacent to the uppermost conductive layer in the circuit structure CS. Specifically, the first conductive layer M1 may be disposed on the planarization layer PLN. In some embodiments, the first conductive layer M1 may be directly disposed on the planarization layer PLN, as shown in FIG. 6. In such condition, in the manufacturing process of the circuit structure CS, the planarization layer PLN may be disposed at first, and then the first conductive layer M1 may be directly disposed on the planarization layer PLN. Although it is not shown in the figure, in some embodiments, other layers may be included between the planarization layer PLN and the first conductive layer M1. In some embodiments, as shown in FIG. 6, the planarization layer PLN may be disposed between the first conductive layer M1 and the insulating layer I1. That is, after the second conductive layer M2 is formed, the insulating layer I1 may be formed at first, and then the planarization layer PLN is formed, and then the first conductive layer M1 is formed on the planarization layer PLN. In such condition, two insulating layers may be included between the first conductive layer M1 and another conductive layer (that is, the second conductive layer M2) adjacent to the first conductive layer M1, that is, the insulating layer I1 and the planarization layer PLN, and the via V1 used for electrically connecting the first conductive layer M1 and the second conductive layer M2 may be formed by removing a portion of the insulating layer I1 and a portion of the planarization layer PLN. In some embodiments, only the planarization layer PLN may be included between the first conductive layer M1 and the second conductive layer M2, that is, the planarization layer PLN may replace the insulating layer I1. In such condition, after the second conductive layer M2 is formed, the planarization layer PLN may be formed on the second conductive layer M2, and then the first conductive layer M1 may be formed on the planarization layer PLN. The planarization layer PLN may include any material that can provide a flat surface to facilitate the formation of the first conductive layer M1 thereon. The material of the planarization layer PLN may be the same as or different from the materials of the planarization layer PL1 and the planarization layer PL2, it is not limited in the present embodiment. The material of the planarization layer PLN may be different from the materials of other insulating layers (such as the insulating layer I1 and the insulating layer 12) in the circuit structure CS. In other words, in the circuit structure CS, the material of at least one of the insulating layers between the first conductive layer M1 and the second conductive layer M2 (that is, the planarization layer PLN) may be different from the material of other insulating layers (such as the insulating layer I1 and the insulating layer 12). The planarization layer PLN has good affinity with the insulating layer I1, or van der waals force may be included between the planarization layer PLN and the insulating layer I1. Therefore, the material satisfying the above-mentioned conditions may be selected as the material of the planarization layer PLN. Through the disposition of the planarization layer PLN in the circuit structure CS, the possibility that the manufacturing process of high-density I/O points or wires (for example, formed by the first conductive layer M1) in the circuit structure CS is affected by the uneven surface may be reduced. After the circuit structure CS is disposed on the target substrate TS, the electronic device E0′ shown in FIG. 6 may be formed.

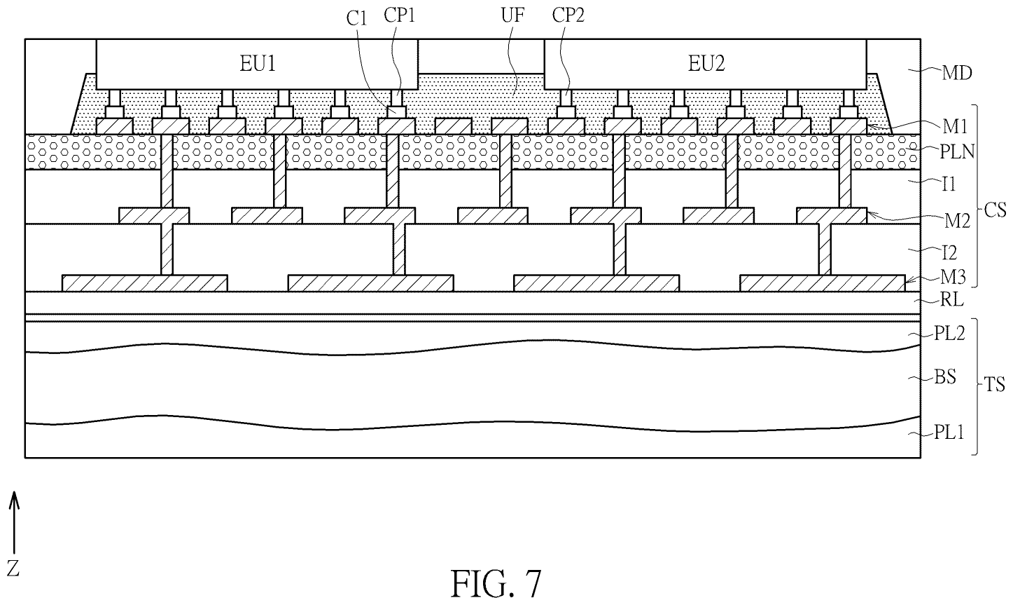

According to the present embodiment, after the electronic device E0′ shown in FIG. 6 is formed, other electronic devices may be formed through the electronic device E0′, such as the electronic device E2 shown below. Specifically, as shown in FIG. 7, after the electronic device E0′ is formed, the manufacturing method of the electronic device E2 may further include disposing at least one electronic element at a side of the circuit structure CS adjacent to the first conductive layer M1. Specifically, after the circuit structure CS is formed, the conductive elements C1 may be disposed on the first conductive layer M1 (or the conductive portions P1 of the first conductive layer M1), and the electronic element EU1 and the electronic element EU2 may be bonded to the circuit structure CS through the conductive elements C1. In detail, the conductive pads CP1 of the electronic element EU1 and the conductive pads CP2 of the electronic element EU2 may contact the conductive elements C1, thereby being bonded to the circuit structure CS through the conductive elements C1. In such condition, the circuit structure CS may be disposed between the target substrate TS and the electronic element EU1 (and the electronic element EU2). The target substrate TS may provide support during the disposition of the electronic element EU1 and the electronic element EU2. The features of the electronic element EU1 and the electronic element EU2 may refer to the contents mentioned above, and will not be redundantly described. It should be noted that although it is not shown in the figure, the electronic element EU1 and the electronic element EU2 may be electrically connected to each other through the circuit structure CS (for example, the first conductive layer M1 in the circuit structure CS) in some embodiments. After the electronic element EU1 and the electronic element EU2 are disposed, the manufacturing method of the electronic device E2 may further include the step of disposing the underfill layer UF and the molding layer MD, and the detail thereof may refer to the contents mentioned above, which will not be redundantly described.

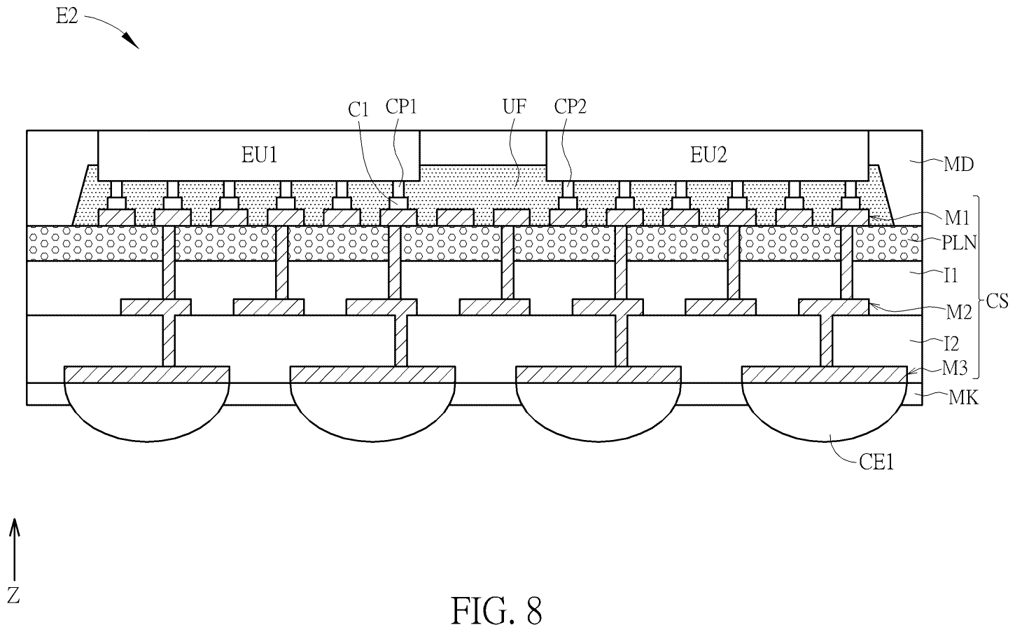

After the electronic element EU1 and the electronic element EU2 are disposed, the manufacturing method of the electronic device E2 may further include removing the target substrate TS and disposing at least one connecting element CE1 at a side of the circuit structure CS adjacent to the third conductive layer M3. Specifically, as shown in FIG. 8, after the electronic element EU1 and the electronic element EU2 are disposed, the target substrate TS may be separated from the circuit structure CS by removing the release layer RL. It should be noted that after the release layer RL is removed, the anti-warpage layer AW1 may also be separated from the circuit structure CS. Therefore, the third conductive layer M3 of the circuit structure CS may be exposed. After that, the connecting element CE1 may be disposed corresponding to the third conductive layer M3 (or the conductive portions P2 of the third conductive layer M3) and contact the third conductive layer M3 (or the conductive portions P2 of the third conductive layer M3), such that the connecting element CE1 may be electrically connected to the circuit structure CS. In some embodiments, as shown in FIG. 8, a solder mask MK may be disposed at a side of the circuit structure CS adjacent to the third conductive layer M3 before disposing the connecting element CE1, and the disposition position of the connecting element CE1 may be defined in the solder mask MK. Specifically, the portion of the solder mask MK corresponding to the conductive portion P2 of the third conductive layer M3 may be removed to expose at least a portion of the conductive portion P2, and then the connecting element CE1 may be disposed corresponding to the exposed portion of the conductive portion P2. After the above-mentioned processes are completed, the electronic device E2 shown in FIG. 8 may be formed. It should be noted that the structure of the electronic device E2 is not limited to what is shown in FIG. 8 and may further include other suitable elements or layers.

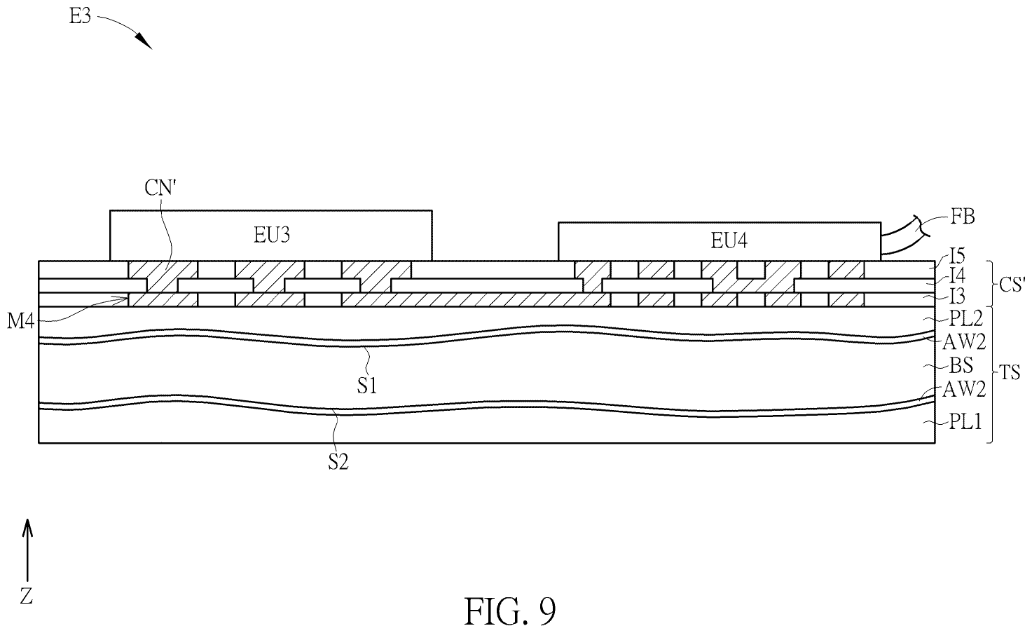

Referring to FIG. 9, FIG. 9 schematically illustrates a cross-sectional view of an electronic device according to a third embodiment of the present disclosure. The manufacturing method of the electronic device E3 of the present embodiment may refer to the contents of the manufacturing method M100 mentioned above. Specifically, the target substrate TS may be provided at first, and then the circuit structure CS' may be disposed on the target substrate TS. According to the present embodiment, in the manufacturing process of the target substrate TS, an anti-warpage layer AW2 may be disposed at least at a side of the base layer BS before disposing the planarization layer PL1 and the planarization layer PL2 respectively at two sides of the base layer BS. Specifically, as shown in FIG. 9, after the flattening process of the base layer BS, the anti-warpage layers AW2 may be disposed on the surface S1 and/or below the surface S2 of the base layer BS at first, and then the planarization layers are disposed. In some embodiments, as shown in FIG. 9, the anti-warpage layers AW2 may respectively be disposed at two sides of the base layer BS, that is, the anti-warpage layers AW2 are respectively disposed on the surface S1 and below the surface S2. In such condition, the base layer BS may be disposed between the two anti-warpage layers AW2. In some embodiments, the anti-warpage layer AW2 may be disposed only at a side of the base layer BS. For example, the anti-warpage layer AW2 may be disposed on the surface S1 or below the surface S2. After the anti-warpage layer(s) AW2 is disposed, the disposition of the planarization layer PL1 and the planarization layer PL2 may be performed to form the target substrate TS. In other words, the target substrate TS of the present embodiment may further include at least one anti-warpage layer AW2 disposed between the base layer BS and at least one of the planarization layer PL1 and the planarization layer PL2. In the embodiment that the target substrate TS includes two anti-warpage layers AW2 respectively at two sides of the base layer BS, the thicknesses of the two anti-warpage layers AW2 may be the same or different. In addition, the coefficients of thermal expansion of the two anti-warpage layers AW2 may be the same or different. The anti-warpage layer AW2 may include any suitable organic material or inorganic material. By making the target substrate TS include the anti-warpage layer AW2, the possibility that the manufacturing process of the elements on the target substrate TS is affected by the warping of the target substrate TS may be reduced. The above-mentioned feature that the target substrate TS includes the anti-warpage layer AW2 may be applied to the embodiments of the present disclosure.

After the target substrate TS is formed, the circuit structure CS′ may be disposed on the target substrate TS. The circuit structure CS′ may include at least one conductive layer and at least one insulating layer. For example, as shown in FIG. 9, the circuit structure CS′ may include a conductive layer M4, a conductive element CN′, an insulating layer 13, an insulating layer 14 and an insulating layer 15, but not limited thereto. The conductive layer M4 is disposed in the insulating layer 13, and the conductive element CN′ is disposed in the insulating layer 14 and the insulating layer 15 and is electrically connected to the conductive layer M4. It should be noted that the circuit structure CS′ shown in FIG. 9 is exemplary, and the actual structure of the circuit structure CS′ is not limited to what is shown in FIG. 9. In some embodiments, the circuit structure CS′ may include a structure formed by stacking conductive layers and insulating layers. In some embodiments, the circuit structure CS′ may be the circuit structure CS in any one of the embodiments mentioned above.

According to the present embodiment, after the circuit structure CS′ is disposed, at least one electronic element may be disposed on the circuit structure CS′ to form the electronic device E3. For example, as shown in FIG. 9, after the circuit structure CS′ is disposed on the target substrate TS, the electronic element EU3 and the electronic element EU4 may be disposed on the circuit structure CS′ (or disposed at a side of the circuit structure CS′ opposite to the target substrate TS), but not limited thereto. That is, the electronic device E3 may include at least one electronic element disposed at a side of the circuit structure CS′ opposite to the target substrate TS. In addition, in the present embodiment, the target substrate TS may serve as the substrate of the electronic device E3, that is, the target substrate TS may not be removed in the manufacturing process of the electronic device E3. The electronic element EU3 and the electronic element EU4 may be electrically connected to the circuit structure CS′ (or the conductive element CN′ and/or the conductive layer M4 in the circuit structure CS′). For example, the conductive layers (including the conductive layer M4 and the conductive element CN′) in the circuit structure CS′ may form the wires or other suitable elements electrically connected to the electronic element EU3 and/or the electronic element EU4. In addition, the electronic element EU3 may further be electrically connected to the electronic element EU4 through the circuit structure CS′ (such as the conductive layer M4 and the conductive element CN′). In an embodiment, the electronic element EU3 may include application-specific integrated circuit (ASIC) chip, and the electronic element EU4 may include optical engine and may be connected to an optical fiber FB, but not limited thereto. In other embodiments, the electronic element EU3 and the electronic element EU4 may include other suitable electronic elements according to the type or purpose of the electronic device E3. By taking the target substrate TS as the substrate of the electronic device E3, the stability of the electronic elements (such as the electronic element EU3 and the electronic element EU4) disposed on the target substrate TS may be improved, thereby reducing the situation of poor coupling between the electronic elements (for example, the electronic element EU4 and the optical fiber FB, but not limited thereto). Therefore, the reliability of the electronic device E3 may be improved.

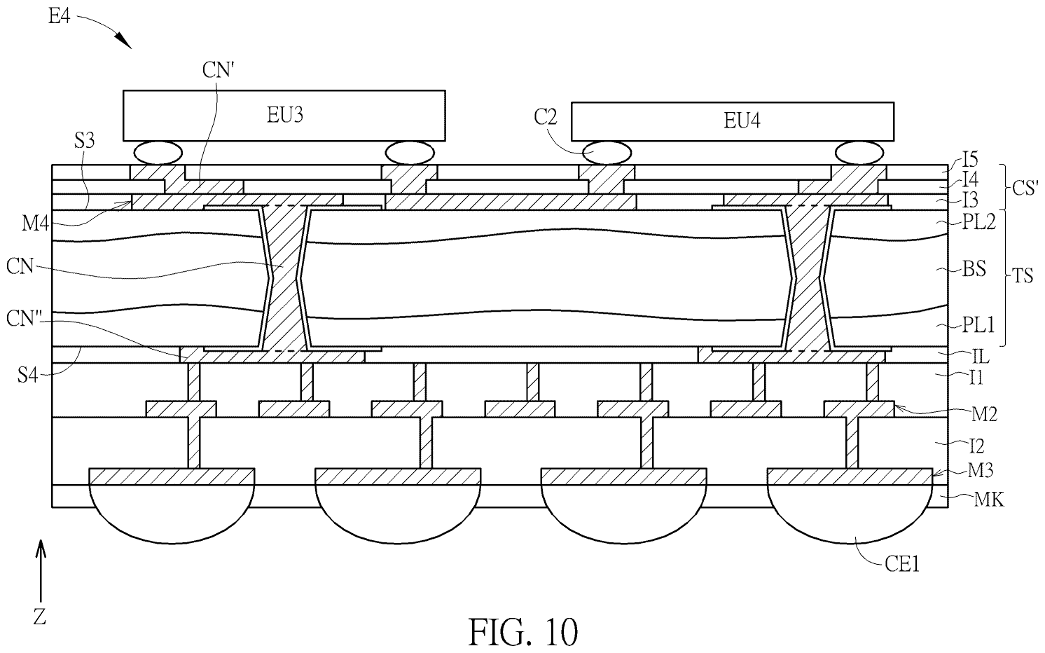

Referring to FIG. 10, FIG. 10 schematically illustrates a cross-sectional view of an electronic device according to a fourth embodiment of the present disclosure. One of the main differences between the electronic device E4 of the present embodiment and the electronic device E3 shown in FIG. 9 is the structural design of the target substrate TS. According to the present embodiment, after the target substrate TS is formed, the manufacturing method of the electronic device E4 may further include forming at least one via VH in the target substrate TS. FIG. 10 for example shows the structure in which the target substrate TS includes two vias VH, but not limited thereto. The via VH may penetrate the target substrate TS. In such condition, the via VH may connect the top surface (that is, the surface S3) and the bottom surface (that is, the surface S4) of the target substrate TS, or in other words, the sidewall of the via VH is connected between the surface S3 and the surface S4. In the present embodiment, the via VH may be formed by performing a modification process and an etching process on the target substrate TS, but not limited thereto. In detail, a modification process may be performed on a portion of the target substrate TS corresponding to the predetermined disposition position of the via VH, such that the structure of the portion of the target substrate TS may be weakened. The modification process may for example include a laser modification process, but not limited thereto. After that, an etching process may be performed on the target substrate TS to remove the modified portion of the target substrate TS, thereby forming the via VH penetrating the target substrate TS. “The portion of the target substrate TS” mentioned above may include a portion of the base layer BS, a portion of the planarization layer PL1 and a portion of the planarization layer PL2. In other words, the via VH may be formed by removing a portion of the base layer BS, a portion of the planarization layer PL1 and a portion of the planarization layer PL2, but not limited thereto. In some embodiments, when the target substrate TS further includes the anti-warpage layer AW2 mentioned above, the via VH may further be formed by removing a portion of the anti-warpage layer AW2. According to some embodiments, the target substrate TS may include a plurality of base layers BS and a plurality of planarization layers (the planarization layer PL1 and the planarization layers PL2) alternately stacked along the direction Z. In detail, another base layer BS may be disposed on the planarization layer PL2, and another planarization layer may be provided on the another base layer BS, such that the thickness variation of the target substrate TS is less than or equal to 3 μm, wherein the materials of these base layers BS may be the same or different, the thicknesses of these base layers BS may be the same or different, and the coefficients of thermal expansion of these base layers BS may be the same or different. For example, in the direction Z, the thickness of the base layer BS away from the electronic element EU3 may be greater than the thickness of the base layer BS adjacent to the electronic element EU3, and the coefficient of thermal expansion of the base layer BS away from the electronic element EU3 may be less than the coefficient of thermal expansion of the base layer BS adjacent to the electronic element EU3.

According to the present embodiment, the manufacturing method of the electronic device E4 may further include forming a conductive element CN in the via VH. Specifically, after the via VH is formed, the material of the conductive element CN may be filled into the via VH to form the conductive element CN. The conductive element CN may fully fill the via VH, but not limited thereto. The conductive element CN may include copper (Cu), aluminum (Al), other suitable metals or combinations of the above-mentioned materials. In some embodiments, as shown in FIG. 10, after the via VH is formed, a buffer layer BF may be disposed in the via VH at first, and then the disposition of the conductive element CN may be performed. The buffer layer BF may be disposed along the sidewall of the via VH, or the buffer layer BF may cover the sidewall of the via VH, but not limited thereto. In some embodiments, the buffer layer BF may further extend on the surfaces (that is, the surface S3 and the surface S4) of the target substrate TS. The buffer layer BF may include any suitable organic insulating material or inorganic insulating material. It should be noted that although the buffer layer BF shown in FIG. 10 is a single layer structure, it is not limited in the present embodiment. In some embodiments, the buffer layer BF may include a multi-layer structure.

The manufacturing method of the electronic device E4 of the present embodiment may further include disposing the circuit structure CS′ on the target substrate and disposing at least one electronic element (such as the electronic element EU3 and the electronic element EU4) on the circuit structure CS′, wherein the details thereof may refer to the contents mentioned above and will not be redundantly described. It should be noted that compared with the embodiment shown in FIG. 9, the electronic element EU3 and/or the electronic element EU4 may be electrically connected to the circuit structure CS′ through the conductive elements C2 in the present embodiment, but not limited thereto. The structure of the circuit structure CS′ may refer to FIG. 9 and related contents above, and will not be redundantly described. The circuit structure CS′ may be electrically connected to the conductive element CN disposed in the via VH. For example, the conductive element CN′ in the circuit structure CS′ may be electrically connected to the conductive layer M4, and the conductive layer M4 may contact the conductive element CN, but not limited thereto. Therefore, the electronic element EU3 and/or the electronic element EU4 may be electrically connected to the conductive element CN through the conductive element CN′ and the conductive layer M4. In addition, the manufacturing method of the electronic device E4 of the present embodiment may further include disposing a connecting element CE1 at a side of the target substrate TS opposite to the circuit structure CS′ (as shown in FIG. 8). Specifically, a conductive element CN″, an insulating layer IL, an insulating layer I1, a conductive layer M2, an insulating layer 12, a conductive layer M3, a connecting element CE1 and a solder mask MK may be formed below the surface S4 of the target substrate TS, but not limited thereto. The conductive element CN″ may be located in the insulating layer IL and contact the conductive element CN. The layers or elements below the insulating layer IL may refer to the structure shown in FIG. 8 and related contents mentioned above, and will not be redundantly described. The conductive layer M2 may be electrically connected to the conductive element CN″, and the conductive layer M3 may be electrically connected to the conductive layer M2. Therefore, the conductive element CN may be electrically connected to the connecting element CE1 through the conductive element CN″, the conductive layer M2 and the conductive layer M3. In such condition, the electronic elements (such as the electronic element EU3 and the electronic element EU4) disposed on the circuit structure CS′ may be electrically connected to the connecting element CE1 through the circuit structure CS′, the conductive element CN disposed in the via VH, the conductive element CN″, the conductive layer M2 and the conductive layer M3. In some embodiments, although it is not shown in the figure, the connecting element CE1 may be electrically connected to another electronic element, and in such condition, the electronic element EU3 and/or the electronic element EU4 may be electrically connected to the another electronic element through the circuit structure CS′, the conductive element CN, the conductive element CN″, the conductive layer M2, the conductive layer M3 and the connecting element CE1.

In summary, an electronic device and a manufacturing method thereof are provided by the present disclosure, wherein the electronic device may include a target substrate, or the target substrate may be used in the manufacturing process of the electronic device. The target substrate may include a base layer processed by a flattening process and the planarization layers disposed at two sides of the base layer respectively to reduce the thickness variation of the target substrate. Therefore, the flatness or stability of the elements or layers disposed on the target substrate may be improved, thereby improving the reliability of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a target substrate, comprising following steps:
(a) providing a base layer;
(b) performing a flattening step on the base layer, and then measuring a first thickness variation of the base layer;
(c) disposing two planarization layers respectively at two sides of the base layer to form the target substrate; and
(d) measuring a second thickness variation of the target substrate, wherein the second thickness variation is less than the first thickness variation; and
disposing a circuit structure on the target substrate.

2. The manufacturing method of claim 1, wherein when the measured first thickness variation is greater than 20 micrometers, the manufacturing method further comprises a following step before the step (c):
(e) performing the step (b) repeatedly until the measured first thickness variation is less than or equal to 20 micrometers.

3. The manufacturing method of claim 1, wherein when the measured second thickness variation is greater than 3 micrometers, the manufacturing method further comprises following steps:
(f) removing the planarization layers; and
(g) performing the step (c) and the step (d) again,
wherein the step (f) and the step (g) are performed repeatedly until the measured second thickness variation is less than or equal to 3 micrometers.

4. The manufacturing method of claim 1, wherein when the measured second thickness variation is greater than 3 micrometers, the manufacturing method further comprises performing a flattening step on the planarization layers repeatedly until the measured second thickness variation is less than or equal to 3 micrometers.

5. The manufacturing method of claim 1, wherein the circuit structure comprises a plurality of conductive layers, the plurality of conductive layers comprises a first conductive layer closest to the target substrate and a second conductive layer farthest from the target substrate, the first conductive layer comprises a plurality of first conductive portions, the second conductive layer comprises a plurality of second conductive portions, and a size of one of the plurality of first conductive portions is less than a size of one of the plurality of second conductive portions.

6. The manufacturing method of claim 5, further comprising:
removing the target substrate; and
disposing at least one electronic element at a side of the circuit structure adjacent to the first conductive layer.

7. The manufacturing method of claim 6, further comprising disposing at least one connecting element at a side of the circuit structure adjacent to the second conductive layer.

8. The manufacturing method of claim 1, wherein the circuit structure comprises a plurality of conductive layers, the plurality of conductive layers comprises a first conductive layer farthest from the target substrate and a second conductive layer closest to the target substrate, the first conductive layer comprises a plurality of first conductive portions, the second conductive layer comprises a plurality of second conductive portions, and a size of one of the plurality of first conductive portions is less than a size of one of the plurality of second conductive portions.

9. The manufacturing method of claim 8, further comprising disposing at least one electronic element at a side of the circuit structure adjacent to the first conductive layer, wherein the circuit structure is disposed between the target substrate and the at least one electronic element.

10. The manufacturing method of claim 9, further comprising:
removing the target substrate; and
disposing at least one connecting element at a side of the circuit structure adjacent to the second conductive layer.

11. The manufacturing method of claim 1, further comprising:
forming a via in the target substrate;
forming a conductive element in the via; and
disposing a connecting element at a side of the target substrate opposite to the circuit structure,
wherein the circuit structure is electrically connected to the connecting element through the conductive element.

12. The manufacturing method of claim 1, wherein the manufacturing method further comprises disposing an anti-warpage layer at least at one side of the base layer before disposing the two planarization layers respectively at the two sides of the base layer.

13. An electronic device, comprising:
a target substrate, comprising:
a base layer; and
two planarization layers respectively disposed at two sides of the base layer; and
a circuit structure disposed on the target substrate,
wherein the base layer has a first thickness variation, the target substrate has a second thickness variation, and the second thickness variation is less than the first thickness variation.

14. The electronic device of claim 13, wherein the first thickness variation is less than or equal to 20 micrometers.

15. The electronic device of claim 13, wherein the second thickness variation is less than or equal to 3 micrometers.

16. The electronic device of claim 13, further comprising at least one electronic element disposed at a side of the circuit structure opposite to the target substrate.

17. The electronic device of claim 13, further comprising:
a connecting element disposed at a side of the target substrate opposite to the circuit structure,
wherein the target substrate has a via, a conductive element is disposed in the via, and the circuit structure is electrically connected to the connecting element through the conductive element.

18. The electronic device of claim 13, further comprising at least one anti-warpage layer disposed between the base layer and at least one of the two planarization layers.

19. The electronic device of claim 13, wherein the base layer comprises glass.

20. The electronic device of claim 13, wherein transmittances of the two planarization layers are greater than 70%.
